(19) United States
(12) Patent Application Publication
(10) Pub. No.: US 2014/0334119 A1
(43) Pub. Date: Nov. 13, 2014

(54) ANTI-EMI SHIELDING ASSEMBLY AND ELECTRONIC DEVICE USING THE SAME

(71) Applicant: HON HAI PRECISION INDUSTRY CO., LTD., NEW TAIPEI (TW)

(72) Inventor: YU-HUA HO, NEW TAIPEI (TW)

(73) Assignee: HON HAI PRECISION INDUSTRY CO., LTD., New Taipei (TW)

(21) Appl. No.: 13/947,110

(22) Filed: Jul. 22, 2013

(30) Foreign Application Priority Data
May 8, 2013 (TW) 102116316

(51) Int. Cl. H05K 9/00

(52) U.S. Cl. CPC H05K 9/0039
USPC 361/753

(57) ABSTRACT

An exemplary shielding assembly includes a printed circuit board (PCB) and a shielding case. The PCB includes a sensitive circuit and a grounding layer. A groove extends from a top surface of the PCB down into the inside of the PCB, and the groove is in communication with the grounding layer. The shielding case is inserted into the groove and covers the sensitive circuit, and the shielding case is electrically connected with the grounding layer.

### BACKGROUND

1. Technical Field

The present disclosure relates to electronic devices, and more particularly to a shielding assembly of an electronic device for shielding electromagnetic radiation.

2. Description of Related Art

In order to protect electronic components on a printed circuit board (PCB) of an electronic device from electromagnetic interference (EMI), shielding cases are generally employed to cover the electronic components. Generally, the shielding case overlies the electronic components and is connected to a surface of the PCB. With this structure, the shielding case protects the electronic components from electromagnetic radiation that propagates in directions from outside the shielding case toward the surface of the PCB. However, electromagnetic radiation coming from the exterior of the PCB can still intrude into the electronic components via slots between the layers of the interior of the PCB. When this happens, the efficiency of protection of the electronic components from EMI is low.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a perspective view of an electronic device in accordance with an exemplary embodiment of the present disclosure, wherein the electronic device comprises a shielding assembly.

FIG. 2 is an exploded, side cross-sectional view of the shielding assembly of

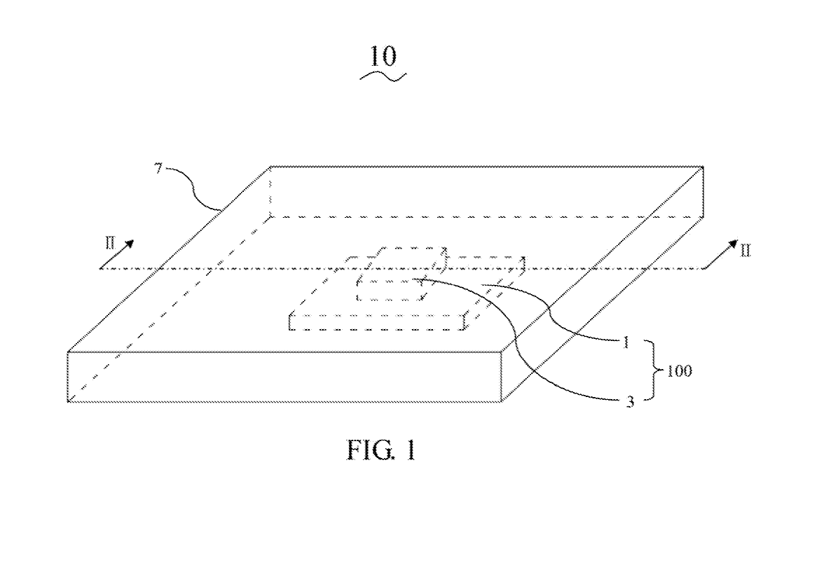

FIG. 1, corresponding to line II-II thereof, showing the shielding assembly in accordance with a first exemplary embodiment of the present disclosure.

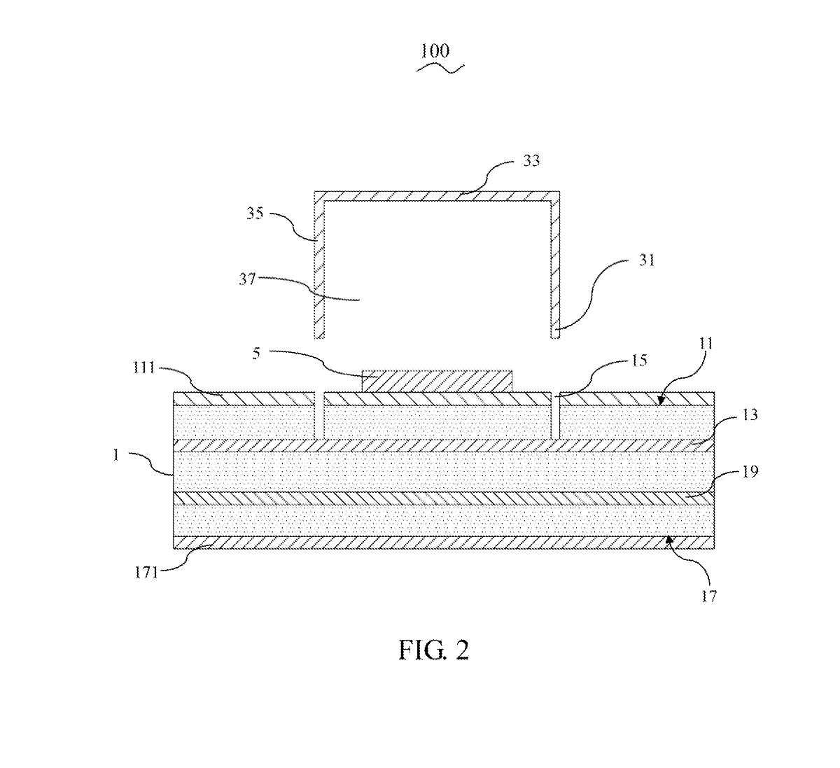

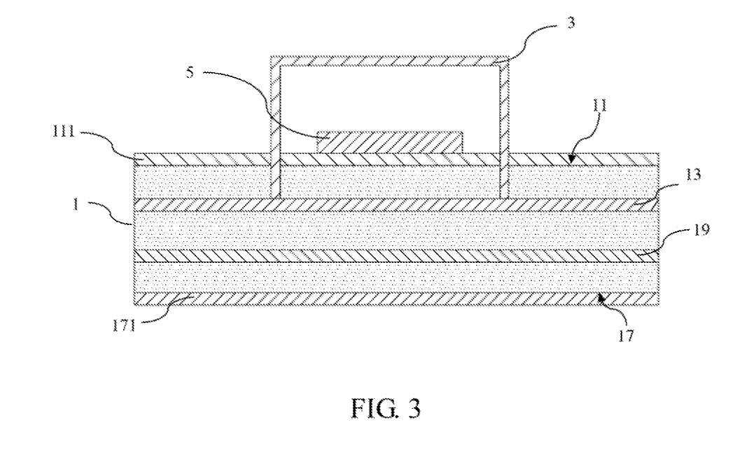

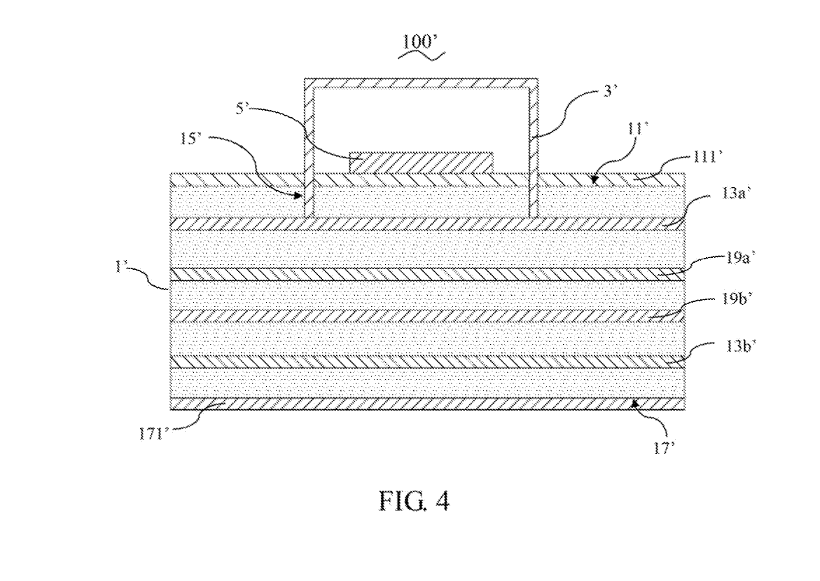

FIG. 3 is similar to FIG. 2, but showing the shielding assembly assembled.

FIG. 4 is a side cross-sectional view of a shielding assembly in accordance with a second exemplary embodiment of the present disclosure.

### DETAILED DESCRIPTION

The disclosure is illustrated by way of example and not by way of limitation in the figures of the accompanying drawings in which like reference numerals indicate the same or similar elements. It should be noted that references to “an” or “one” embodiment in this disclosure are not necessarily to the same embodiment, and such references can mean “at least one.”

FIG. 1 is a perspective view of an electronic device in accordance with an exemplary embodiment of the present disclosure. The electronic device 10 comprises a housing 7, and a shielding assembly 100 received in the housing 7. In the embodiment, the electronic device 10 is a portable phone. Alternatively, the electronic device 10 may be any of various other kinds of portable electronic devices, such as a notebook, a tablet, a digital photo frame, etc.

Referring also to FIG. 2, the shielding assembly 100 includes a PCB 1, and a shielding case 3 mounted on the PCB 1. The PCB 1 includes a sensitive circuit 5 and a grounding layer 13. In this description, the term “sensitive circuit” refers to any electrical circuit that is liable to sustain EMI and therefore should be protected from EMI. The grounding layer 13 is located inside the PCB 1. The PCB 1 defines a groove 15 in communication with the grounding layer 13. In the embodiment, the groove 15 extends from a top surface 11 of the PCB 1 down into the inside of the PCB 1 toward the grounding layer 13. The groove 15 is in communication with the grounding layer 13 inside the PCB 1.

Referring also to FIG. 3, the PCB 1 is a multi-layer PCB. In the first embodiment, the PCB 1 includes four electrical layers, namely a first signal layer 111, a second signal layer 171, the grounding layer 13 and a power layer 19. The first signal layer 111 is located on the top surface 11 of the PCB 1, and is used for assembling electric components. The second signal layer 171 is located on a bottom surface 17 of the PCB 1. The grounding layer 13 and the power layer 19 are located inside the PCB 1. The four electrical layers are separated from each other by three interleaving insulative layers (not labeled).

The sensitive circuit 5 is mounted on the first signal layer 111. The groove 15 surrounds the sensitive circuit 5 on the top surface 11 of the PCB 1. In the embodiment, the groove 15 is in the shape of a rectangular frame when viewed from above. The sensitive circuit 5 typically includes sensitive electric components and sensitive wires that are easily interfered with by electromagnetic radiation. For example, the sensitive circuit 5 may be a filter circuit prone to EMI. In an alternative embodiment, the sensitive circuit 5 may be mounted on the power layer 19.

Referring to FIG. 3, in the illustrated embodiment, the grounding layer 13 is the second electrical layer of the PCB 1. The groove 15 extends from a top surface 11 of the first signal layer 111 down into the inside of the PCB 1 toward the grounding layer 13. The groove 15 is in communication with the grounding layer 13. Alternatively, the grounding layer 13 is the third electrical layer of the PCB 1, and the power layer 19 is the second electrical layer of the PCB 1. In such case, correspondingly, the groove 15 traverses the first signal layer 111 and the power layer 19, and terminates at and communicates with the grounding layer 13.

In the embodiment, the shielding case 3 is in the shape of a four-sided (rectangular) box. The shielding case 3 is inserted into the groove 15 and electrically contacts the grounding layer 13. The shielding case 3 covers the sensitive circuit 5 to protect the sensitive circuit 5 from EMI.

In detail, the shielding case 3 includes a top wall 33, and a peripheral sidewall 35 extending down from the periphery of the top wall 33. The top wall 33 and the sidewall 35 collectively form a receiving space 37 therebetween. The sidewall 35 has a bottom end 31. In assembly, the sensitive circuit 5 is received in the receiving space 37. In the embodiment, the sidewall 35 is four-sided. The bottom end 31 of the shielding case 3 is correspondingly in the shape of a rectangle, which matches the shape of the rectangular groove 15. The bottom end 31 of the shielding case 3 is electrically connected with the grounding layer 13 by a welding process.

In the embodiment, the material of the shielding case 3 is iron. Alternatively, the material of the shielding case 3 may be copper.

In assembly, the sidewall 35 of the shielding case 3 is inserted into the groove 15 of the PCB 1, with the sensitive circuit 5 received in the receiving space 37 of the shielding case 3. The bottom end 31 of the sidewall 35 is electrically connected with the grounding layer 13. Thus the shielding case 3 shields the sensitive circuit 5 on the top surface 11 of the PCB 1. Furthermore, the shielding case 3 and the grounding layer 13 of the PCB 1 collectively form a grounding loop, which even further protects the sensitive circuit 5 from EMI.

With the above-described structure, because the shielding case 3 and the grounding layer 13 inside the PCB 1 collectively form a complete grounding loop, electromagnetic radiation at the exterior of the PCB 1 can not intrude into the sensitive circuit 5 via slots (not shown) between the layers of the PCB 1. Thus the sensitive circuit 5 can be completely protected from EMI.

FIG. 4 is a side cross-sectional view of a shielding assembly 100′ in accordance with a second exemplary embodiment of the present disclosure. The structure of the shielding assembly 100′ is substantially the same as that of the shielding assembly 100, except that the number of electrical layers of a PCB 1′ of the shielding assembly 100′ is greater than the number of electrical layers of the PCB 1. In the embodiment, the PCB 1′ includes six electrical layers. In detail, the PCB 1′ includes a first signal layer 111′ located on a top surface 11′ of the PCB 1′, a second signal layer 171′ located on a bottom surface 17′ of the PCB 1′, and two grounding layers 13a′, 13b′ and two power layers 19a′, 19b′ inside the PCB 1′. The grounding layer 13a′ is the second electrical layer of the PCB 1′. A groove 15′ extends from a top surface of the first signal layer 111′ down into the inside of the PCB 1′ toward the grounding layer 13a′ (i.e., second electrical layer). The groove 15′ is in communication with the grounding layer 13a′. The shielding case 3′ is inserted into the groove 15′ and is electrically connected with the grounding layer 13a′. Thus the shielding case 3 shields a sensitive circuit 5′ on the top surface 11′ of the PCB 1′.

Alternatively, the number of electrical layers of the PCB 1, 1′ may be changed according to practical requirements. For example, the PCB 1, 1′ can have three electrical layers, or five electrical layers, or seven or more electrical layers.

In summary, the shielding assembly 100, 100′ protects the sensitive circuit 5, 5′ from EMI completely, due to the grounding loop cooperatively formed by the shielding case 3, 3′ and the grounding layer 13, 13′ inside the PCB 1, 1′. Thus, unlike with conventional shielding assemblies, electromagnetic radiation coming from the exterior of the PCB 1, 1′ can not intrude into the sensitive circuit 5, 5′ via slots between the layers of the PCB 1, 1′.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A shielding assembly, comprising:
a printed circuit board (PCB) comprising an electrical circuit, and a grounding layer inside the PCB, the PCB defining a groove extending from a top surface of the PCB down into the inside of the PCB, wherein the groove is in communication with the grounding layer; and
a shielding case inserted into the groove and covering the electrical circuit, wherein the shielding case is electrically connected with the grounding layer to protect the electrical circuit from electromagnetic interference (EMI).

2. The shielding assembly of claim 1, wherein the shielding case comprises a top wall and a sidewall extending down from a periphery of the top wall, the top wall and the sidewall collectively define a receiving space therebetween, and the sidewall is inserted into the groove of the PCB and electrically connected with the grounding layer, with the electrical circuit received in the receiving space of the shielding case.

3. The shielding assembly of claim 2, wherein the groove is in the shape of a rectangular frame, and a bottom end of the sidewall of the shielding case is correspondingly in the shape of a rectangle which matches the shape of the groove.

4. The shielding assembly of claim 3, wherein the PCB further comprises a first signal layer located on the top surface of the PCB, a second signal layer located on a bottom surface of the PCB, and a power layer located inside the PCB, and the groove further extends through the first signal layer.

5. An electronic device comprising:
a housing; and
a shielding assembly received in the housing, the shielding assembly comprising:
a printed circuit board (PCB) comprising an electrical circuit, and a grounding layer inside the PCB, the PCB defining a groove extending from a top surface of the PCB down into the inside of the PCB, wherein the groove is in communication with the grounding layer; and
a shielding case inserted into the groove and covering the electrical circuit, wherein the shielding case is electrically connected with the grounding layer to protect the electrical circuit from electromagnetic interference (EMI).

6. The electronic device of claim 5, wherein the shielding case comprises a top wall and a sidewall extending down from a periphery of the top wall, the top wall and the sidewall collectively define a receiving space therebetween, and the sidewall is inserted into the groove of the PCB and electrically connected with the grounding layer, with the electrical circuit received in the receiving space of the shielding case.

7. The electronic device of claim 6, wherein the groove is in the shape of a rectangular frame, and a bottom end of the sidewall of the shielding case is correspondingly in the shape of a rectangle which matches the shape of the groove.

8. The electronic device of claim 7, wherein the PCB further comprises a first signal layer located on the top surface of the PCB, a second signal layer located on a bottom surface of the PCB, and a power layer located inside the PCB, and the groove further extends through the first signal layer.
